(19) United States
(12) Patent Application Publication
(10) Pub. No.: US 2026/0371665 A1
(43) Pub. Date: Nov. 19, 2026

(54) SEMICONDUCTOR DEVICE AND METHOD OF MANUFACTURING THE SAME

(71) Applicants: Yunbin GAO, Suzhou (CN); SUZHOU MACROCORE SEMICONDUCTOR CO., LTD., Suzhou (CN)

(72) Inventors: Zhenzhong ZHANG, Suzhou (CN); Yunbin GAO, Suzhou (CN); Jianyong HAO, Suzhou (CN)

(73) Assignees: Yunbin GAO, Suzhou (CN); SUZHOU MACROCORE SEMICONDUCTOR CO., LTD., Suzhou (CN)

(21) Appl. No.: 19/731,405

(22) Filed: Jul. 6, 2026

Related U.S. Application Data
(63) Continuation of application No. PCT/CN2025/083392, filed on Mar. 19, 2025.

(51) Int. Cl. H10D 62/10; H10D 30/01; H10D 30/66; H10D 62/832

(52) U.S. Cl. CPC H10D 62/109; H10D 30/0297; H10D 30/668; H10D 62/127; H10D 62/8325

(57) ABSTRACT

A semiconductor device includes cells arranged in an array. Each cell includes a silicon carbide body, a gate trench, two shielding regions, and a conductive connection portion. The silicon carbide body includes opposite first and second surfaces. The gate trench extends from the first surface into the silicon carbide body, and a conductive gate electrode is disposed in the gate trench. The two shielding regions extend from the first surface into the silicon carbide body and are disposed on two sides of the gate trench along a first direction. Two adjacent cells in the first direction share one of the shielding regions. The conductive connection portion is disposed on a side of the shielding region away from the second surface and electrically connects conductive gate electrodes in gate trenches of two adjacent cells in a second direction. The first direction is perpendicular to the second direction.

### CROSS-REFERENCE TO RELATED APPLICATIONS

This application is a continuation of International Application No. PCT/CN 2025/083392, filed on Mar. 19, 2025, the content of which is incorporated herein by reference in its entirety.

### TECHNICAL FIELD

The present disclosure relates to the technical field of semiconductor manufacturing, and in particular, to a semiconductor device and a method of manufacturing the semiconductor device.

### BACKGROUND

In a trench-gate silicon carbide (SiC) MOSFET device, a gate oxide layer at the bottom and sidewalls of a gate trench may be subjected to a high electric-field strength during a blocking operation. For such a device, a principal technical issue is that existing trench-gate SiC MOSFET structures may not simultaneously provide effective electric-field shielding for the gate oxide layer, high cell integration, and a simplified manufacturing process. Accordingly, a device structure in which a gate trench, shielding regions, and electrical connections between gate electrodes of adjacent cells are coordinated may be desirable.

### SUMMARY

In a first aspect, embodiments of the present disclosure provide a semiconductor device, including a plurality of cells arranged in an array. Each cell includes a silicon carbide body, a gate trench, two shielding regions, and a conductive connection portion. The silicon carbide body includes a first surface and a second surface disposed opposite the first surface. The gate trench extends from the first surface into the silicon carbide body, and a conductive gate electrode is disposed in the gate trench. The two shielding regions extend from the first surface into the silicon carbide body and are disposed on two sides of the gate trench at intervals along a first direction, and two adjacent cells in the first direction share one of the shielding regions. The conductive connection portion is disposed on a side of the shielding region away from the second surface and electrically connects conductive gate electrodes in gate trenches of two adjacent cells in a second direction. The first direction is perpendicular to the second direction.

In a second aspect, embodiments of the present disclosure provide a method of manufacturing a semiconductor device. The semiconductor device includes a plurality of cells arranged in an array. The method includes providing a silicon carbide body including a first surface and a second surface disposed opposite the first surface, forming two shielding regions extending from the first surface of the silicon carbide body into the silicon carbide body, forming a gate trench extending from the first surface of the silicon carbide body into the silicon carbide body, and forming a conductive connection portion on a side of the shielding region away from the second surface. The two shielding regions are disposed on two sides of the gate trench at intervals along a first direction, two adjacent cells in the first direction share one of the shielding regions, the gate trench is disposed between the two shielding regions along the first direction, and conductive gate electrodes in gate trenches of two adjacent cells in a second direction are electrically connected via the conductive connection portion. The first direction is perpendicular to the second direction.

### BRIEF DESCRIPTION OF THE DRAWINGS

To describe the technical solutions in the embodiments of the present disclosure more clearly, the drawings used in the description of the embodiments are briefly described below. The drawings described below illustrate only some embodiments of the present disclosure. A person of ordinary skill in the art may obtain other drawings based on these drawings without creative effort.

FIG. 1 is a schematic diagram of a semiconductor device according to an embodiment of the present disclosure.

FIG. 2 is a cross-sectional view taken along line AA in FIG. 1 according to an embodiment of the present disclosure.

FIG. 3 is a cross-sectional view taken along line BB in FIG. 1 according to an embodiment of the present disclosure.

FIG. 4 is a schematic diagram of a silicon carbide body according to an embodiment of the present disclosure.

FIG. 5 is a schematic diagram of the semiconductor device after a gate trench is formed according to an embodiment of the present disclosure.

FIG. 6 is a schematic diagram of the semiconductor device after a gate structure is formed according to an embodiment of the present disclosure.

FIG. 7 is a schematic diagram of the semiconductor device after a shielding region is formed according to an embodiment of the present disclosure.

FIG. 8 is a schematic diagram of another semiconductor device after a shielding region is formed according to an embodiment of the present disclosure.

FIG. 9 is a schematic diagram of another semiconductor device according to an embodiment of the present disclosure.

FIG. 10 is a cross-sectional view taken along line AA in FIG. 9 according to an embodiment of the present disclosure.

FIG. 11 is a cross-sectional view taken along line BB in FIG. 9 according to an embodiment of the present disclosure.

FIG. 12 is a schematic diagram of two cells in a first direction according to an embodiment of the present disclosure.

FIG. 13 is a schematic diagram of the semiconductor device after a body region and a source region are formed according to an embodiment of the present disclosure.

FIG. 14 is a schematic diagram of the semiconductor device after a conductive connection portion is formed according to an embodiment of the present disclosure.

FIG. 15 is a schematic diagram of the semiconductor device after an interlayer dielectric layer is formed according to an embodiment of the present disclosure.

FIG. 16 is a schematic diagram of the semiconductor device after a source connection portion is formed according to an embodiment of the present disclosure.

FIG. 17 is a flowchart of a method of manufacturing a semiconductor device according to an embodiment of the present disclosure.

### DETAILED DESCRIPTION OF THE EMBODIMENTS

Example embodiments will now be described more fully with reference to the accompanying drawings. The example embodiments may, however, be embodied in many forms and are not to be construed as limited to the examples set forth herein. Rather, these embodiments are provided so that the present disclosure will be thorough and complete and will fully convey the concepts of the example embodiments to those skilled in the art. The described features, structures, or characteristics may be combined in any suitable manner in one or more embodiments.

In addition, the drawings are merely schematic illustrations of the present disclosure and are not necessarily drawn to scale. The same reference numerals in the drawings denote the same or similar parts, and repeated descriptions thereof may be omitted. Some block diagrams shown in the drawings are functional entities and do not necessarily correspond to physically or logically independent entities. Such functional entities may be implemented in software, in one or more hardware modules or integrated circuits, or in different networks and/or processor devices and/or microcontroller devices.

The terms “having,” “containing,” “including,” “comprising,” and the like are open-ended terms that indicate the presence of stated structures, elements, or features, but do not preclude the presence of additional elements or features. The articles and pronouns “a,” “an,” and “the” are intended to include both the singular and the plural, unless the context clearly indicates otherwise.

In the drawings, relative doping concentrations are illustrated by placing a “−” or “+” next to the doping type “n” or “p.” For example, “n−” denotes a doping concentration lower than that of an “n” doped region, and an “n+” doped region has a doping concentration higher than that of an “n” doped region. Doped regions having the same indicated doping concentration do not necessarily have the same absolute doping concentration. For example, two different “n” doped regions may have the same or different absolute doping concentrations. Two adjoining doped regions having the same conductivity type and different dopant concentrations form a unipolar junction, for example an n/n+ junction or a p/p+ junction, along a boundary surface between the two doped regions. A dopant concentration profile orthogonal to the unipolar junction at the unipolar junction may exhibit a step or an inflection point at which the dopant concentration profile changes from concave to convex, or vice versa.

A major constituent of a layer or structure formed from a chemical compound or an alloy is an element whose atoms form the chemical compound or alloy. For example, nickel and silicon are major constituents of a nickel silicide layer, and copper and aluminum are major constituents of a copper-aluminum alloy.

Before specific embodiments of the semiconductor device are described, the following technical context of power devices and SiC trench-gate MOSFETs is provided. Power devices are core components of modern electronic power systems and play an important role in power management, energy conversion, and power processing. As power electronics technology continues to develop toward higher frequency, higher density, and higher reliability, conventional silicon-based power devices may fail to meet increasingly stringent performance requirements due to material limitations. Wide-bandgap semiconductors may provide high operating frequency, high power density, high breakdown voltage, and strong radiation resistance due to their relatively wide bandgaps. Among wide-bandgap semiconductors, silicon carbide (SiC) may provide a high critical breakdown electric field, high thermal conductivity, and high saturation electron drift velocity. Compared with silicon-based insulated-gate bipolar transistors, SiC metal-oxide-semiconductor field-effect transistors may provide lower switching loss and a higher operating frequency because of their unipolar device structure and high saturation electron drift velocity. Trench-gate SiC MOSFETs have attracted attention for high cell density, low conduction loss, and excellent switching performance.

In this context, a trench-gate MOSFET provides a device structure different from a conventional planar MOSFET. Compared with a conventional planar MOSFET, a trench-gate design changes a conduction channel from a lateral channel to a vertical channel, thereby reducing cell size, reducing on-resistance, and eliminating a junction field-effect transistor (JFET) effect. However, trench-gate technology is limited by current process capability and by reliability concerns associated with a gate oxide layer. More specifically, electric-field concentration at the bottom of a gate trench may reduce long-term reliability of the semiconductor device.

For SiC devices in particular, because of inherent electrical characteristics of the SiC material, the gate oxide layer at the bottom and sidewalls of the trench may not withstand a high electric-field strength during a blocking operation of the device, and therefore the conventional silicon-based trench-gate MOSFET device structure may not be directly used for SiC devices. A key issue in conventional SiC MOSFET device structures is how to effectively shield the electric field applied to the gate oxide layer at the above positions. Existing mainstream trench-gate SiC MOSFET structures are generally developed around this issue and mainly use a p+ implanted region to suppress the electric field in the gate oxide layer.

These limitations may lead to deficiencies in electric-field shielding, process compatibility, and high-temperature characteristics, and may further result in a complicated process, poor high-temperature conduction characteristics, large cell dimensions, and stringent requirements for high-energy ion implantation processes.

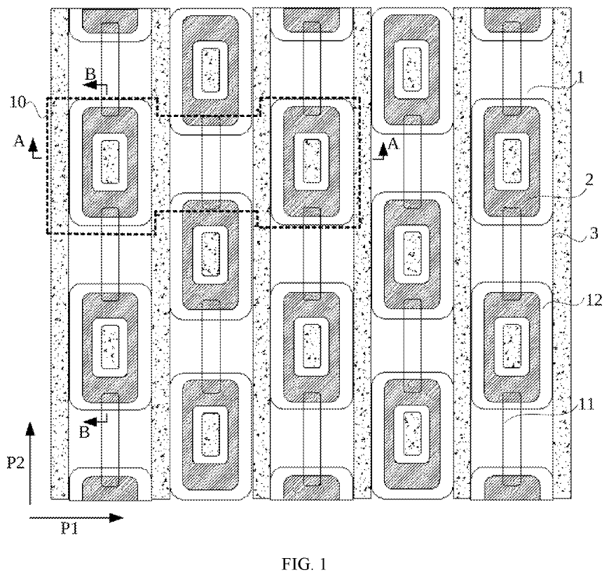

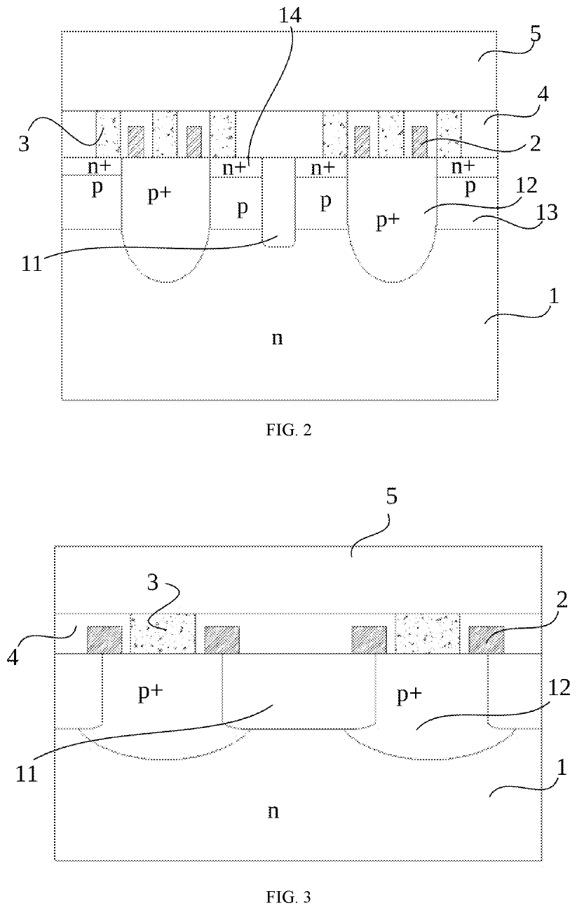

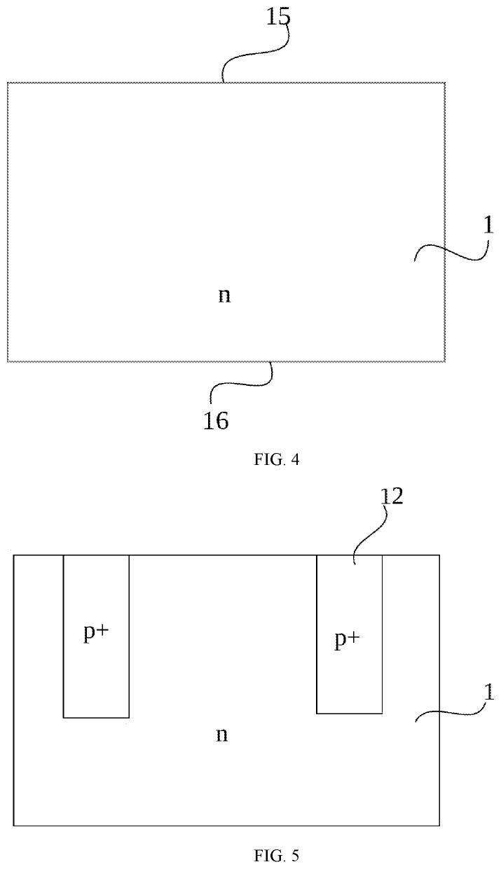

In view of the foregoing technical context, the present disclosure provides a semiconductor device. Referring to FIG. 1, the semiconductor device includes a plurality of cells 10 arranged in an array. Referring to FIGS. 2 and 3, each cell 10 may include a silicon carbide body 1, a gate trench 11, two shielding regions 12, and a conductive connection portion 2. Referring to FIG. 4, the silicon carbide body 1 includes a first surface 15 and a second surface 16 disposed opposite the first surface 15. The gate trench 11 extends from the first surface 15 into the silicon carbide body 1, and a conductive gate electrode is disposed in the gate trench 11. The two shielding regions 12 extend from the first surface 15 into the silicon carbide body 1 and are disposed on two sides of the gate trench 11 at intervals along the first direction P1. Two adjacent cells 10 in the first direction P1 share one shielding region 12. The conductive connection portion 2 is disposed on a side of the shielding region 12 away from the second surface 16. Conductive gate electrodes in gate trenches 11 of two adjacent cells 10 in the second direction P2 are electrically connected via the conductive connection portion 2. The first direction P1 is perpendicular to the second direction P2.

It may be noted that FIG. 1 includes a plurality of cells 10, one of which is selected by a dashed-line box. One cell 10 may include the structure shown in FIG. 2, namely the silicon carbide body 1, one gate trench 11 completely enclosed by a dashed-line frame, two shielding regions 12, and the conductive connection portion 2.

In the device structure described above, by disposing the shielding regions 12 on two sides of the gate trench 11 and causing adjacent cells 10 to share one shielding region 12, a staggered arrangement is formed. This design provides shielding in two dimensions, namely the first direction P1 and the second direction P2, and suppresses high electric-field strength at the bottom and sidewalls of the gate trench 11. Electric-field stress in the gate oxide layer is thereby reduced. The operating lifetime of the gate oxide layer may be extended, and voltage-withstanding performance and reliability of the device may be improved. Because the staggered arrangement allows adjacent cells 10 to share the shielding region 12, repeated arrangement of shielding regions 12 is reduced, and a higher degree of integration of the cell 10 may be achieved without increasing additional area. The cell size may also be further reduced, and area utilization of the device may be improved. Current density per unit area may be increased, and the overall performance of the device may be enhanced. As the cell 10 is reduced in size and the layout of the shielding region 12 is optimized, the device structure becomes more compact and the on-resistance is reduced.

Further, in the device structure described above, the optimized layout of the shielding region 12 may provide the intended shielding effect with a relatively shallow depth, thereby reducing dependence on high-energy ion implantation processes and further improving the conduction characteristics of the device. In particular, under high-temperature conditions, on-resistance may be reduced more significantly and energy efficiency of the device may be improved. The structure may avoid a complicated secondary epitaxy process or multiple trench etching processes, thereby simplifying the overall process flow. Because of the dual shielding effect of the shielding region 12, the device may exhibit improved stability under severe operating conditions such as high voltage, high current, and high temperature. The structure may prevent breakdown caused by electric-field concentration. Device robustness may thereby be improved, and the device may be more suitable for high-efficiency power applications, such as electric vehicles and industrial variable-frequency drives.

In some examples, referring to FIG. 4, the silicon carbide body 1 includes the first surface 15 and the second surface 16 disposed opposite each other. By way of example, the silicon carbide body 1 may be a polytype such as 15R-SiC, 2H-SiC, 4H-SiC, or 6H-SiC. In addition to silicon and carbon as major constituents, the silicon carbide body 1 may include dopant atoms, such as nitrogen (N), phosphorus (P), beryllium (Be), boron (B), aluminum (Al), and/or gallium (Ga). The silicon carbide body 1 may further include unwanted impurities, such as hydrogen and/or oxygen. The silicon carbide body 1 may include the first surface 15 on a front side and the opposite second surface 16 on a back side.

It may be noted that the conductivity type of the silicon carbide body 1 may be a first conductivity type. The first conductivity type may be n-type or p-type. In this description and below, the conductivity type of the silicon carbide body 1 is referred to as the first conductivity type and, in the illustrated examples, is n-type.

In the present disclosure, the first conductivity type and a second conductivity type are used to distinguish between n-type and p-type. When the first conductivity type is n-type, the second conductivity type is p-type. When the first conductivity type is p-type, the second conductivity type is n-type.

In some examples, referring to FIG. 5, the shielding regions extend from the first surface 15 into the silicon carbide body 1 and are spaced apart from each other in the first direction P1.

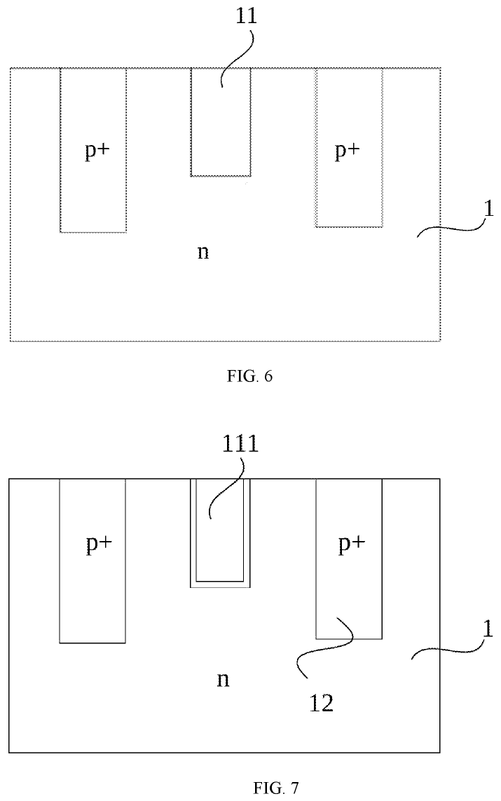

In some examples, referring to FIG. 6, the gate trench 11 extends from the first surface 15 into the silicon carbide body 1. The gate trench 11 extending from the first surface 15 into the silicon carbide body 1 may be formed in the silicon carbide body 1 by a mask etching process. The formed gate trench 11 has sidewalls and a bottom. The gate trench 11 may be disposed between the two shielding regions 12 in the first direction P1.

Referring to FIG. 7, a gate structure 111 may be disposed in the gate trench 11. The gate structure 111 may include a conductive gate electrode of the first conductivity type and a gate oxide layer disposed at least between the body region 13 and the conductive gate electrode. The gate oxide layer contacts the sidewalls of the gate trench 11, and the conductive gate electrode may be, for example, a polysilicon gate.

In some examples, referring to FIG. 7, the shielding region 12 is spaced apart from the gate trench 11, and the bottom of the shielding region 12 is closer to the second surface 16 than the bottom of the gate trench 11. The conductivity type of the shielding region 12 is the second conductivity type. Specifically, when the second conductivity type is p-type, a p-type body-region mask may first be made using a photolithography process, and a p-type impurity such as boron or aluminum may then be implanted using the p-type body-region mask to form a p-type shielding region 12.

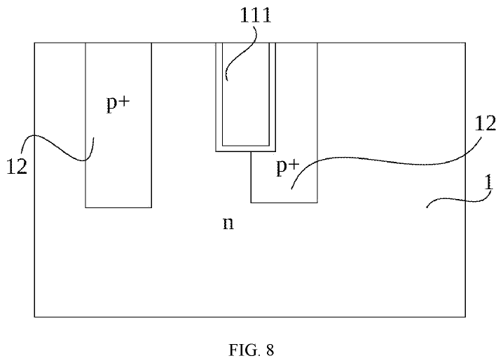

In some examples, as shown in FIG. 7, the two shielding regions 12 are disposed symmetrically with respect to the gate trench 11. This symmetric structure may balance electric-field distribution, thereby improving electrical performance and reliability of the device. In other examples, as shown in FIG. 8, one of the shielding regions 12 extends from the first surface 15 into the silicon carbide body 1 and extends along the first direction P1 such that the shielding region 12 contacts both the sidewalls and the bottom of the gate trench 11. This asymmetric design further enhances the electric-field shielding effect of the shielding region 12 with respect to the gate trench 11. In particular, under high-voltage and high-electric-field operating conditions, electric-field stress in the gate oxide layer may be significantly reduced, and the operating lifetime of the device may be extended.

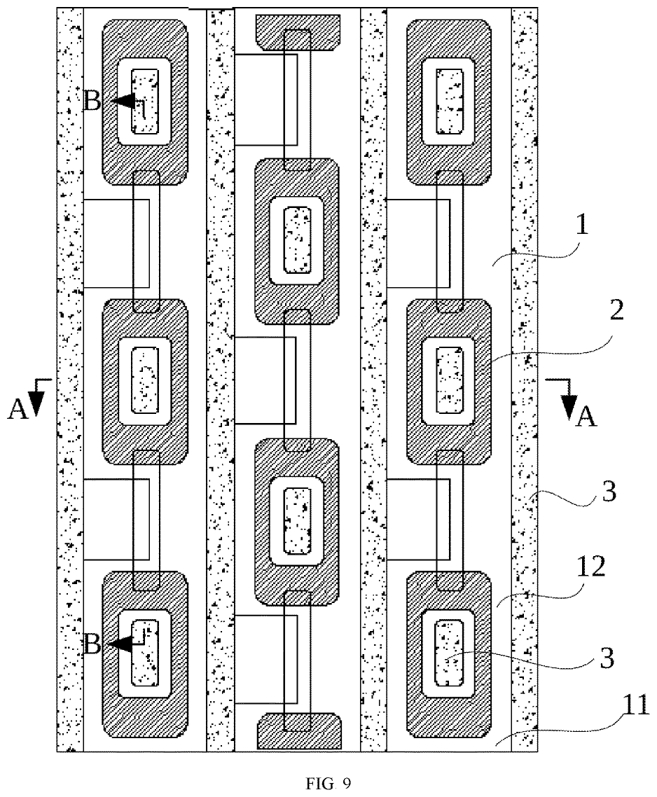

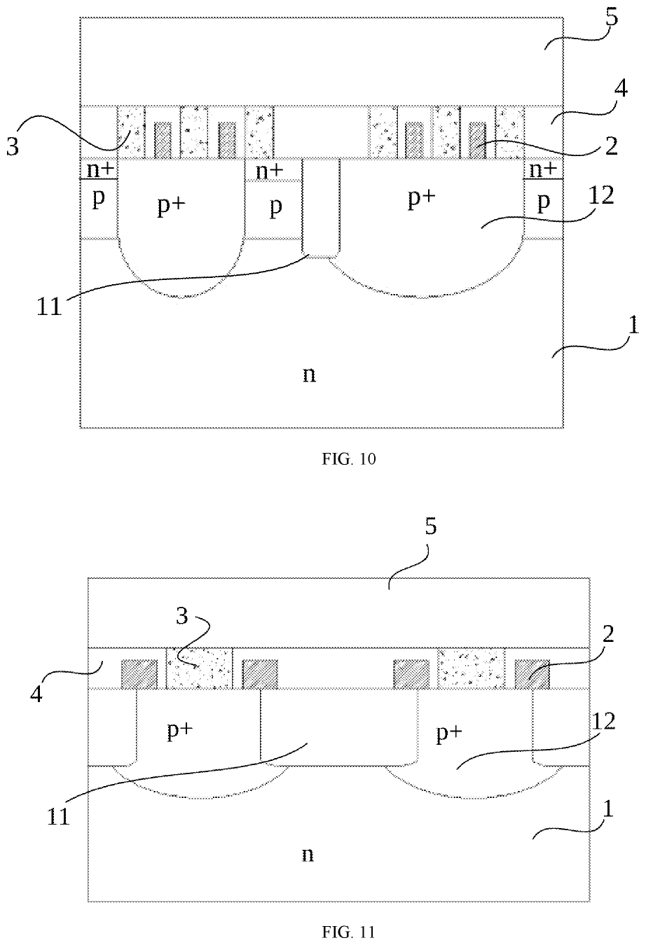

Referring to FIGS. 9, 10, and 11, when the two shielding regions 12 extend from the first surface 15 into the silicon carbide body 1 and extend in the first direction P1, the shielding regions 12 may further optimize the electric field at the bottom of the gate trench 11.

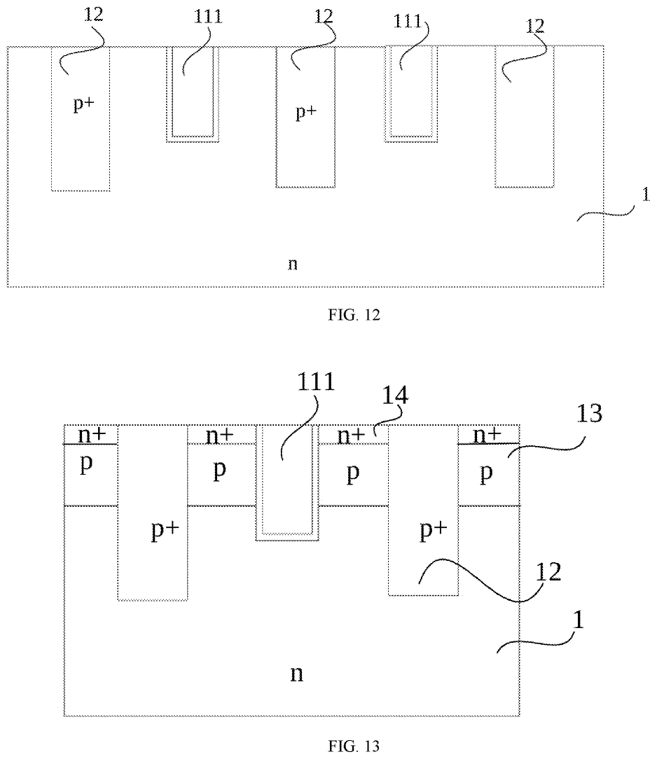

In some examples, referring to FIG. 12, two adjacent cells 10 in the first direction P1 share one shielding region 12, so that the density of cells 10 in the semiconductor device may be increased.

In some examples, referring to FIG. 13, the cell 10 further includes a body region 13 and a source region 14. The body region 13 and the source region 14 are oppositely doped and form a p-n junction. The source region 14 has the first conductivity type, and the body region 13 has the second conductivity type. The body region 13 contacts the sidewalls of the gate trench 11, the source region 14 contacts the sidewalls of the gate trench 11, and the source region 14 is located between the body region 13 and the first surface 15. Thus, the body region 13 has the second conductivity type, the source region 14 has the first conductivity type, and the source region 14 is located between the body region 13 and the first surface 15. When the first conductivity type is n-type, n-type impurity implantation may be used to form an n-type source region 14. The doping concentration of the shielding region 12 is greater than the doping concentration of the body region 13.

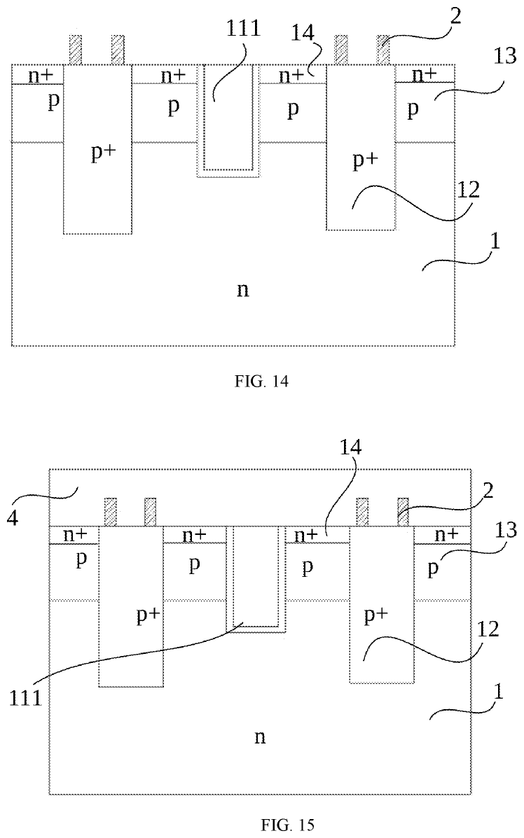

In some examples, as shown in FIG. 14, the conductive connection portion 2 is disposed on a side of the shielding region 12 away from the second surface 16. Accordingly, conductive gate electrodes in the gate trenches 11 of two adjacent cells 10 in the second direction P2 may be reliably electrically connected to each other via the conductive connection portion 2. The second direction P2 is perpendicular to the first direction P1. This layout improves electrical performance and increases structural integration of the device. With this connection configuration, the device may maintain a low-resistance connection while improving overall current distribution uniformity and signal transmission efficiency. The arrangement of the conductive connection portion 2 also facilitates further miniaturization and higher performance of the device.

The conductive connection portion 2 may be made of polysilicon. The polysilicon conductive connection portion 2 partially covers the conductive gate electrode in the gate trench 11 of an adjacent cell 10 in the second direction P2. With this design, the plurality of cells 10 may be reliably electrically connected, thereby improving the overall electrical performance and integration level of the device.

In some examples, referring to FIG. 15, the cell 10 may further include an interlayer dielectric layer 4. The interlayer dielectric layer 4 is disposed on a side of the silicon carbide body 1 away from the second surface 16 and covers the source region 14, the body region 13, the gate structure 111 in the gate trench 11, and the conductive connection portion 2. This design further improves electrical performance and reliability of the device. The interlayer dielectric layer 4 covers the source region 14, the body region 13, the gate structure 111, and the conductive connection portion 2, thereby isolating electric-field interference between different functional regions, reducing leakage current and parasitic effects, and improving electrical performance of the device. The interlayer dielectric layer 4 also provides additional protection for the device by protecting the device from external factors such as humidity and impurities, thereby helping maintain stable operation of the device in complex operating environments.

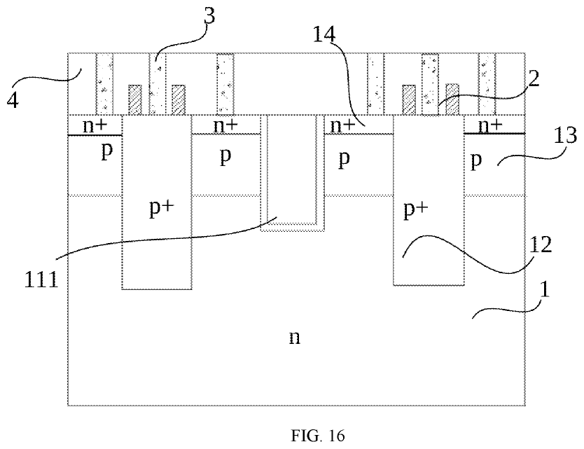

In some examples, referring to FIGS. 2 and 16, the cell 10 may further include a metal electrode 5. The metal electrode 5 is disposed on a side of the interlayer dielectric layer 4 away from the first surface 15. The interlayer dielectric layer 4 insulates the metal electrode 5 from the silicon carbide body 1 and the conductive connection portion 2. A contact hole may be formed in the interlayer dielectric layer 4 by etching. A plurality of contact holes may be provided, including a source contact hole and a shielding-region contact hole. The contact holes penetrate the interlayer dielectric layer 4. A source connection portion 3 may then be formed in the source contact hole and the shielding-region contact hole, so that the source connection portion 3 is connected between the shielding region 12 and the metal electrode 5 and between the source region 14 and the metal electrode 5, thereby completing the connection between the metal electrode 5 and the source of the semiconductor device.

The interlayer dielectric layer 4 provides reliable insulation and isolation between the metal electrode 5 and each of the silicon carbide body 1 and the conductive connection portion 2, thereby preventing leakage current and parasitic effects and improving electrical performance and reliability of the device. Isolation provided by the interlayer dielectric layer 4 makes the electric-field distribution more uniform, reduces electric-field concentration, and further improves the voltage-withstanding capability of the device. The source connection portion 3 extends through the interlayer dielectric layer 4 and directly connects the shielding region 12, the source region 14, and the metal electrode 5, thereby forming a low-resistance current path. Source contact resistance is significantly reduced, and conduction efficiency of the device is improved. The source connection portion 3 also makes current distribution more uniform and reduces local current-density concentration, thereby maintaining stable and reliable operation of the device under high-current operating conditions.

In some examples, the conductive connection portion 2 is an annular conductive connection portion 2. The annular conductive connection portion 2 surrounds the source connection portion 3 connected between the shielding region 12 and the metal electrode 5, and the annular conductive connection portion 2 is spaced apart from the source connection portion 3. By surrounding the source connection portion 3, the annular conductive connection portion 2 provides a compact and efficient electrical connection path. The surrounding structure may provide multi-point contact in a limited space, thereby reducing contact resistance and increasing current transmission efficiency.

In some example embodiments of the present disclosure, with continued reference to FIG. 1, the plurality of cells 10 are arranged in a staggered manner. A projection, along the first direction P1, of one cell 10 partially overlaps a projection, along the first direction P1, of another cell 10 adjacent thereto in the second direction P2. Specifically, rectangular gate trenches 11 and shielding regions 12 are disposed on the silicon carbide body 1 in a staggered arrangement. The width of each gate trench 11 may be any value greater than or equal to 0.2 μm and less than or equal to 1.5 μm, and the depth thereof may be any value greater than or equal to 0.5μm and less than or equal to 1.5 μm. The gate trench 11 may be deeper than the body region by any value greater than or equal to 0.1 μm and less than or equal to 0.5μm. The sidewalls and the bottom surface of each gate trench 11 are lined with a gate oxide layer, the thickness of which may be greater than or equal to 30 nm and less than or equal to 200 nm. The remaining portion of the gate trench 11 is filled with polysilicon.

Gate polysilicon in adjacent trenches in the second direction P2 is interconnected by the conductive connection portion 2. The two ends of the gate trench 11 in the second direction P2 partially overlap with adjacent shielding regions 12. The depth of the shielding region 12 is greater than that of the gate trench 11 by any value greater than or equal to 0.1 μm and less than or equal to 1 μm. The source connection portion 3 in each shielding region 12 is shorted to a source metal electrode 5.

Based on the structure and dimensional relationships described above, the shielding regions 12 are disposed on two sides of the gate trench 11, and adjacent cells 10 share one shielding region 12 to form a staggered arrangement. This design provides shielding in two dimensions, namely the first direction P1 and the second direction P2, and suppresses high electric-field strength at the bottom and sidewalls of the gate trench 11. Electric-field stress in the gate oxide layer is thereby significantly reduced. The operating lifetime of the gate oxide layer may be extended, and voltage-withstanding performance and reliability of the device may be improved. Because the staggered arrangement allows adjacent cells 10 to share the shielding region 12, repeated arrangement of shielding regions 12 is reduced, and a higher degree of integration of the cell 10 may be achieved without increasing additional area. The cell size may also be further reduced, and area utilization of the device may be improved. Current density per unit area may be increased, and overall performance of the device may be enhanced. As the cell 10 is reduced in size and the layout of the shielding region 12 is optimized, the device structure becomes more compact and the on-resistance is reduced.

The optimized layout of the shielding region 12 may also provide the intended shielding effect with a relatively shallow depth, thereby reducing dependence on high-energy ion implantation processes and further improving the conduction characteristics of the device. In particular, under high-temperature conditions, on-resistance may be reduced more significantly and energy efficiency of the device may be improved. The structure may avoid a complicated secondary epitaxy process or multiple trench etching processes, thereby simplifying the overall process flow. Because of the dual shielding effect of the shielding region 12, the device exhibits improved stability under severe operating conditions such as high voltage, high current, and high temperature. The structure may prevent breakdown caused by electric-field concentration. Device robustness may thereby be improved, and the device may be more suitable for high-efficiency power applications, such as electric vehicles and industrial variable-frequency drives.

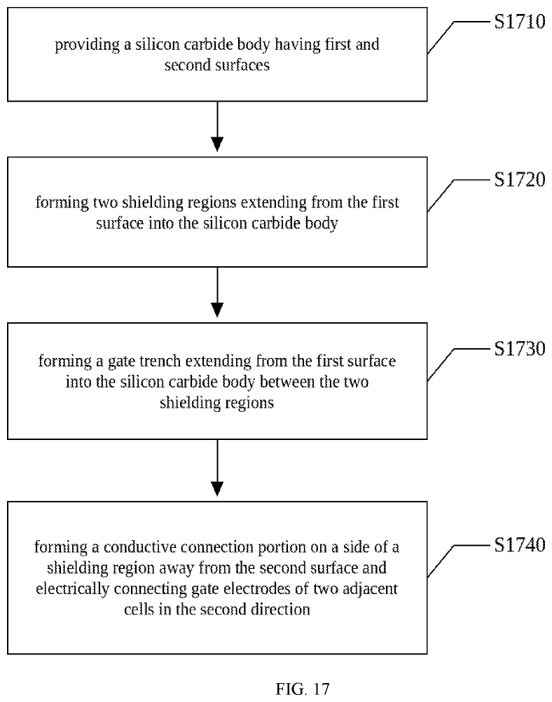

After the semiconductor device has been described above, a method of manufacturing the semiconductor device will be described with reference to FIG. 17. The semiconductor device includes a plurality of cells 10 arranged in an array. A process of forming the cell 10 may include steps S1710 through S1740.

In step S1710, a silicon carbide body is provided. The silicon carbide body includes a first surface and a second surface disposed opposite the first surface.

Specific details of the silicon carbide body have been described above in connection with the semiconductor device. Reference may be made, for example, to the description of FIG. 4, and details are not repeated here.

In step S1720, two shielding regions extending from the first surface of the silicon carbide body into the silicon carbide body are formed. The two shielding regions are disposed at intervals along the first direction P1, and two adjacent cells 10 in the first direction P1 share one shielding region.

In an example embodiment of the present disclosure, referring to FIG. 5, two shielding regions 12 spaced apart in the first direction P1 may be formed in the silicon carbide body 1. The shielding regions 12 extend from the first surface 15 into the silicon carbide body 1. The shielding regions 12 may protect the gate trench 11 and thereby reduce the electric field of the gate structure 111.

In step S1730, a gate trench extending from the first surface of the silicon carbide body into the silicon carbide body is formed. The gate trench is disposed between the two shielding regions in the first direction P1.

In an example embodiment of the present disclosure, referring to FIGS. 6 and 7, when the gate trench 11 is formed, a mask etching process may be used to etch the silicon carbide body 1 to form the gate trench 11. The formed gate trench 11 has sidewalls and a bottom. The specific position of the gate trench 11 may be selected according to design requirements and is not further described in this example embodiment.

Optionally, the two shielding regions 12 are disposed symmetrically with respect to the gate trench 11.

In step S1740, a conductive connection portion is formed on a side of the shielding region away from the second surface. Conductive gate electrodes in gate trenches of two adjacent cells 10 in the second direction P2 are electrically connected via the conductive connection portion, wherein the first direction P1 is perpendicular to the second direction P2.

In some example embodiments of the present disclosure, referring to FIG. 14, after the shielding region 12 is formed, the conductive connection portion 2 may be formed on a side of the shielding region 12 away from the second surface 16. The conductive connection portion 2 may be formed by deposition. Optionally, the conductive connection portion 2 may be polysilicon, that is, the same material as the gate electrode. The conductive connection portion 2 is configured to electrically connect conductive gate electrodes in gate trenches 11 of two adjacent cells 10 in the second direction P2, so that conductive gate electrodes in the plurality of cells 10 are connected.

In some examples, the shielding region 12 may first be formed on the silicon carbide body 1, and may be formed by ion implantation. Specifically, when the second conductivity type is p-type, a p-type body-region mask may first be made using a photolithography process, and a p-type impurity such as boron or aluminum may then be implanted using the p-type body-region mask to form a p-type shielding region 12. The doping concentration of the shielding region 12 is greater than the doping concentration of the body region 13.

After the shielding region 12 is formed, the gate trench 11 may first be formed in the silicon carbide body 1, and the gate structure 111 may be formed in the gate trench 11. The gate structure 111 includes a conductive gate electrode. Formation of the gate trench 11 and formation of the gate structure 111 may refer to the description of the semiconductor device, and details are not repeated here.

Optionally, the gate trench 11 is formed after the shielding region 12 is formed, and then the gate structure 111 is formed inside the gate trench 11. During formation of the gate trench 11, the gate trench 11 may also be formed in part of the shielding region 12.

In some examples, referring to FIG. 13, the method of manufacturing the semiconductor device may further include forming a body region 13 and a source region 14. Specifically, the body region 13 may first be formed in the silicon carbide body 1, and the source region 14 may then be formed between the body region 13 and the first surface 15. The body region 13 and the source region 14 are oppositely doped and form a p-n junction. The source region 14 has the first conductivity type, and the body region 13 has the second conductivity type.

In some examples, the body region 13 contacts the sidewalls of the gate trench 11, the source region 14 contacts the sidewalls of the gate trench 11, and the source region 14 is located between the body region 13 and the first surface 15. Thus, the body region 13 has the second conductivity type, and the source region 14 has the first conductivity type.

Specifically, when the second conductivity type is p-type, a p-type body-region mask may first be made using a photolithography process, and a p-type impurity such as aluminum may then be implanted using the p-type body-region mask to form the p-type body region 13.

The process of forming the body region 13 and the source region 14 may be performed before the gate trench 11 is formed. That is, a dopant is first introduced into the silicon carbide body 1 to form the body region 13 and the source region 14. Then, the gate trench 11 is formed in the silicon carbide body 1 by etching, and the gate structure 111 is formed in the gate trench 11.

The process of forming the body region 13 and the source region 14 may alternatively be performed after at least part of the gate trench 11 structure has been formed. The specific process flow may be adjusted according to design requirements and is not further described in this example embodiment.

After the body region 13 and the source region 14 have been formed, referring to FIG. 14, the conductive connection portion 2 may be formed on the shielding region 12. The conductive connection portion 2 may be made of polysilicon and may be formed by deposition. The conductive connection portion 2 is disposed on a side of the shielding region 12 away from the second surface 16, so that conductive gate electrodes in gate trenches 11 of two adjacent cells 10 in the second direction P2 may be reliably electrically connected via the conductive connection portion 2. The conductive connection portion 2 may be made of polysilicon and may partially cover the conductive gate electrode in the gate trench 11 of a cell 10 adjacent thereto in the second direction P2, thereby establishing electrical connection between the plurality of cells 10. That is, gates of the cells 10 in the semiconductor device are connected via the conductive connection portion 2, sources of the cells 10 are connected through the source connection portion 3 and the metal electrode 5, and the plurality of cells 10 share a common drain.

In some examples, when the semiconductor device is manufactured, the shielding region 12 and the body region 13 may first be formed in the silicon carbide body 1 by boron or aluminum ion implantation. The junction depths of the shielding region 12 and the body region 13 may respectively be greater than or equal to 0.6 μm and less than or equal to 2.5 μm, and greater than or equal to 0.4μm and less than or equal to 1 μm. The source region 14 may then be formed by nitrogen or phosphorus ion implantation, and the junction depth may be any value greater than or equal to 0.1 μm and less than or equal to 0.5 μm. High-temperature activation annealing may then be performed at a temperature greater than or equal to 1600 °C and less than or equal to 1900 °C

Optionally, the gate trench 11 may be formed by a reactive ion etching (RIE) process. The depth of the gate trench 11 may be any value greater than or equal to 0.5 μm and less than or equal to 1.5 μm. Optionally, a rounding process may further be used to improve the bottom profile.

When the gate structure 111 is formed, a gate oxide layer on the sidewalls and bottom may first be formed by thermal oxidation, chemical vapor deposition, or a combination thereof. The gate oxide layer may have a thickness greater than or equal to 30 nm and less than or equal to 200 nm. Gate polysilicon, namely the conductive gate electrode, may then be deposited by chemical vapor deposition to fill the remaining portion of the trench. Excess polysilicon on the wafer surface may be removed by chemical mechanical polishing or another process, and the remaining thickness may be greater than or equal to 0.1 μm and less than or equal to 1.5 μm. A polysilicon pattern may also be formed by an RIE process.

Before the interlayer dielectric layer 4 is formed, as shown in FIG. 14, the conductive connection portion 2 is formed on a side of the shielding region 12 away from the second surface. The conductive connection portion 2 may be formed by chemical vapor deposition or may be formed into a desired shape by an etching process. The conductive connection portion 2 may be made of polysilicon, which is the same material as the conductive gate electrode in the gate structure.

When the interlayer dielectric layer 4 is formed, referring to FIG. 15, the interlayer dielectric layer 4 may be deposited by chemical vapor deposition and reflowed. The thickness of the interlayer dielectric layer 4 may be greater than or equal to 0.2 μm and less than or equal to 1.5 μm. A portion of the interlayer dielectric layer may be selectively removed by a reactive ion etching process to form a contact hole.

A metal may be deposited by a sputtering process. The metal may include Al, AlCu, AlSi, AlSiCu, or a combination thereof, and may have a thickness greater than or equal to 2 μm and less than or equal to 6 μm. A gate metal pattern and a source metal pattern may then be formed by wet etching, RIE etching, or a combination thereof, thereby forming the metal electrode 5. Alternatively, copper (Cu) may be electroplated to form the metal electrode 5, and may have a thickness greater than or equal to 3 μm and less than or equal to 10 μm. The formation method of the metal electrode 5 may also be selected according to design requirements and is not further described in this example embodiment.

In some examples, tungsten (W) may first be deposited by a CVD process and etched back to form the source connection portion 3, and the metal electrode 5 may then be formed by sputtering or electroplating.

In the above embodiments, the description of each embodiment has its own focus. For a part that is not described in detail in one embodiment, reference may be made to the relevant description of another embodiment. The technical features in the above embodiments may be combined in any manner. For conciseness, all possible combinations of the technical features in the above embodiments are not described. However, as long as there is no contradiction among the technical features, the combinations may be considered to fall within the scope recorded in this specification.

Other embodiments of the present disclosure will be apparent to those skilled in the art upon consideration of the specification and practice of the present disclosure described herein. The present disclosure is intended to cover any variation, use, or adaptation of the present disclosure that follows the general principles of the present disclosure and includes common general knowledge or conventional technical means in the art that are not disclosed in the present disclosure.

It may be understood that the present disclosure is not limited to the precise structures described above and shown in the drawings, and that various modifications and changes may be made without departing from the scope of the present disclosure. The scope of the present disclosure is limited only by the appended claims.

What is claimed is:

1. A semiconductor device, comprising a plurality of cells arranged in an array, each cell comprising:
a silicon carbide body comprising a first surface and a second surface disposed opposite the first surface;
a gate trench extending from the first surface into the silicon carbide body, wherein a conductive gate electrode is disposed in the gate trench;
two shielding regions extending from the first surface into the silicon carbide body and disposed on two sides of the gate trench at intervals along a first direction, wherein two adjacent cells in the first direction share one of the shielding regions; and
a conductive connection portion disposed on a side of the shielding region away from the second surface, wherein conductive gate electrodes in gate trenches of two adjacent cells in a second direction are electrically connected via the conductive connection portion, and the first direction is perpendicular to the second direction.

2. The semiconductor device according to claim 1, wherein the conductive connection portion of the cell partially covers the conductive gate electrode in the gate trench of another cell adjacent thereto in the second direction.

3. The semiconductor device according to claim 1, wherein the plurality of cells are arranged in a staggered manner, and along the first direction, a projection of one of the cells partially overlaps a projection of another cell adjacent to the one of the cells in the second direction.

4. The semiconductor device according to claim 1, wherein each cell further comprises:
a body region and a source region, wherein the body region and the source region contact sidewalls of the gate trench, and the source region is located between the body region and the first surface.

5. The semiconductor device according to claim 4, wherein each cell further comprises:
an interlayer dielectric layer disposed on a side of the silicon carbide body away from the second surface and covering the gate trench, the shielding regions, and the conductive connection portion;
a metal electrode disposed on a side of the interlayer dielectric layer away from the first surface; and
a source connection portion extending through the interlayer dielectric layer and connected between a corresponding one of the shielding regions and the metal electrode and between the source region and the metal electrode.

6. The semiconductor device according to claim 5, wherein the conductive connection portion is an annular conductive connection portion, the annular conductive connection portion surrounds the source connection portion connected between a corresponding one of the shielding regions and the metal electrode, and the annular conductive connection portion is spaced apart from the source connection portion.

7. A method of manufacturing a semiconductor device comprising a plurality of cells arranged in an array, wherein forming each cell comprises:
providing a silicon carbide body, the silicon carbide body comprising a first surface and a second surface disposed opposite the first surface;
forming two shielding regions extending from the first surface of the silicon carbide body into the silicon carbide body, wherein the two shielding regions are disposed at intervals along a first direction, and two adjacent cells in the first direction share one of the shielding regions;
forming a gate trench extending from the first surface of the silicon carbide body into the silicon carbide body, wherein the gate trench is disposed between the two shielding regions in the first direction; and
forming a conductive connection portion on a side of the shielding region away from the second surface, wherein conductive gate electrodes in gate trenches of two adjacent cells in a second direction are electrically connected via the conductive connection portion, and the first direction is perpendicular to the second direction.

8. The method according to claim 7, wherein the conductive connection portion comprises polysilicon, and the conductive connection portion of the cell partially covers the conductive gate electrode in the gate trench of another cell adjacent thereto in the second direction.

9. The method according to claim 7, wherein the plurality of cells are arranged in a staggered manner, and along the first direction, a projection of one of the cells partially overlaps a projection of another cell adjacent to the one of the cells in the second direction.

10. The method according to claim 7, further comprising:
forming a body region and a source region, wherein the body region and the source region contact sidewalls of the gate trench, and the source region is located between the body region and the first surface.

11. The method according to claim 10, further comprising:
forming an interlayer dielectric layer, wherein the interlayer dielectric layer is disposed on a side of the silicon carbide body away from the second surface and covers the gate trench, the shielding regions, and the conductive connection portion; and
forming a source connection portion and a metal electrode, wherein the metal electrode is disposed on a side of the interlayer dielectric layer away from the first surface, and the source connection portion extends through the interlayer dielectric layer and is connected between a corresponding one of the shielding regions and the metal electrode and between the source region and the metal electrode.

12. The method according to claim 11, wherein the conductive connection portion is an annular conductive connection portion, the annular conductive connection portion surrounds the source connection portion connected between a corresponding one of the shielding regions and the metal electrode, and the annular conductive connection portion is spaced apart from the source connection portion.
